(19) United States
(12) Patent Application Publication
(10) Pub. No.: US 2021/0050325 A1
(43) Pub. Date: Feb. 18, 2021

(54) LIGHT EMITTING ELEMENT, LIGHT EMITTING DEVICE, AND MANUFACTURING METHOD THEREOF

(71) Applicant: Samsung Display Co., Ltd., Yongin-si (KR)

(72) Inventors: Tae Ho KIM, Yongin-si (KR); Jae Jin LYU, Yongin-si (KR)

(21) Appl. No.: 16/986,009

(22) Filed: Aug. 5, 2020

(30) Foreign Application Priority Data
Aug. 14, 2019 (KR) 10-2019-0099743

(51) Int. Cl. H01L 23/00; H01L 33/62; H01L 25/075; H01L 33/44

(52) U.S. Cl. CPC H01L 24/82; H01L 33/62; H01L 33/20; H01L 33/44; H01L 25/0753

(57) ABSTRACT

A light emitting element, a light emitting device and a manufacturing method thereof are provided. The manufacturing method of the light emitting device includes forming a first electrode and a second electrode spaced apart from each other on a substrate on which the light emitting area is defined; injecting a solution including a light emitting element and a liquid crystal molecule into the light emitting area; and aligning the light emitting element such that the first electrode and the second electrode are electrically coupled; wherein the light emitting element includes a first semiconductor layer; a second semiconductor layer; an active layer interposed between the first semiconductor layer and the second semiconductor layer; an insulation layer formed to surround an outer surface of the active layer; and an organic ligand layer formed on an outer surface of the insulating layer.

### CROSS-REFERENCE TO RELATED APPLICATION

This application claims priority to and the benefit of Korean Patent Application No. 10-2019-0099743 filed in the Korean Intellectual Property Office on Aug. 14, 2019, the entire contents of which are incorporated herein by reference.

### BACKGROUND

### 1. Field

Embodiments of the present disclosure relate to a light emitting element, a light emitting device and a manufacturing method thereof, and, for example, to an ultra-small light emitting element having a nano-scale or micro-scale size, a light emitting device including the same and a manufacturing method thereof.

### 2. Description of the Related Art

An LED element has high light conversion efficiency, very low energy consumption, a semi-permanent life-span and is environmentally-friendly. Accordingly, LED elements have been utilized in many fields such as signal lights, mobile phones, automotive headlamps, outdoor billboards, LCD back light units (LCD BLU), and indoor and outdoor lighting.

Recently, a technology for manufacturing an ultra-small LED element using a material of a highly reliable inorganic crystal structure and manufacturing a light emitting element using the LED element have been developed. For example, a light emitting device constituting a light source using ultra-small LED elements having a size as small as micro-scale or nano-scale and in each light emitting area has been developed. The light emitting device may be used as a light source of various suitable electronic devices such as a display device or a lighting device.

### SUMMARY

An exemplary embodiment of the present disclosure provides a micro or nano-sized micro LED device that facilitates alignment and coupling between two different electrodes.

An exemplary embodiment of the present disclosure provides an alignment method and a light emitting device using the same capable of preventing or reducing an abnormal alignment of an ultra-small LED element by aligning and coupling the ultra-small LED element having a nano-scale or micro-scale size and independently manufactured between two different electrodes.

The features of the present disclosure are not limited to the features mentioned herein above, and other technical features that are not mentioned may be clearly understood to a person of an ordinary skill in the art using the following description.

A manufacturing method of a light emitting device according to an exemplary embodiment of the present disclosure includes forming a first electrode and a second electrode spaced apart from each other on a substrate on which a light emitting area is defined; injecting a solution including a light emitting element and a liquid crystal molecule into the light emitting area; and aligning the light emitting element such that the first electrode and the second electrode are electrically coupled; wherein the light emitting element includes a first semiconductor layer; a second semiconductor layer; an active layer interposed between the first semiconductor layer and the second semiconductor layer; an insulation layer formed to surround an outer surface of the active layer; and an organic ligand layer formed on an outer surface of the insulating layer.

The manufacturing method of the light emitting device may further include heat-treating at a high temperature of 80° C. or more after the aligning.

The manufacturing method of the light emitting device may further include removing a liquid crystal after the heat-treating.

In the removing of the liquid crystal, the liquid crystal may be removed using a solvent including at least one selected from tetrahydrofuran (THF), isopropyl alcohol (IPA), deionized water (Di-water), N-Methyl-2-pyrrolidone (NMP) and acetonitrile.

In the aligning, a direct current voltage or alternating current voltage may be applied to the first electrode and the second electrode.

The first and second electrodes may be side by side to extend in a first direction in at least one area on the substrate.

The manufacturing method of the light emitting device may further include applying an organic insulation layer on the first electrode, the second electrode and the light emitting area before injecting the solution.

The manufacturing method of the light emitting device may further include forming a groove extending in a second direction crossing the first direction in the organic insulation layer through a photo process after the applying the organic insulation layer.

In the forming of the groove, the photo process may be performed using a halftone mask.

A stacked direction of the first semiconductor layer, the active layer and the second semiconductor layer in the light emitting element may be the second direction after the aligning.

The groove may have a width greater than a diameter or a width of the light emitting element.

The injecting the solution may be performed by an inkjet process or a fine drop process of 50 pL or less.

A light emitting element according to another exemplary embodiment of the present disclosure includes a first semiconductor layer; a second semiconductor layer; an active layer interposed between the first semiconductor layer and the second semiconductor layer; an insulation layer formed to surround an outer surface of the active layer; and an organic ligand layer formed on at least a portion of the insulation layer.

The organic ligand layer may include at least one C5 to C24 aliphatic hydrocarbon group or C5 to C20 aromatic hydrocarbon group bonded to a Group 14 element.

The light emitting element further may include a first electrode layer on one side of the first semiconductor layer and a second electrode layer on one side of the second semiconductor layer.

The insulation layer may have a hydroxyl group at one end.

The light emitting element may have a length of 1 μm to 7 μm and an aspect ratio of 1 to 7.

A light emitting device according to another exemplary embodiment of the present disclosure includes a substrate on which a plurality of light emitting areas are defined; first and second electrodes on the substrate and side by side in at least a portion of the light emitting area; and a light emitting element having one end on the first electrode and an other end on the second electrode, wherein the light emitting element includes an organic ligand layer formed on at least a portion of a surface thereof.

The light emitting device may further include an insulating support between the substrate and the light emitting element and including a groove, wherein the light emitting element is in the groove.

The light emitting device may further include a conductive contact layer electrically coupling the one end of the light emitting element and the first electrode, and electrically coupling the other end of the light emitting element and the second electrode.

Features of other embodiments are further described in the detailed description and drawings.

According to exemplary embodiments of the present disclosure, the number of ultra-small LED elements aligned and coupled between two different electrodes among a plurality of ultra-small LED elements may be increased.

In addition, a luminance of each pixel unit in a light emitting device may be increased.

Effects of exemplary embodiments of the present disclosure are not limited by what is illustrated in the above, and more various effects are included in the present specification.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a perspective view of a light emitting element according to an exemplary embodiment of the present disclosure.

FIG. 2 is a cross-sectional view of a light emitting element according to an exemplary embodiment of the present disclosure.

FIGS. 3 and 4 are cross-sectional views showing sequentially a manufacturing method of a light emitting element according to an exemplary embodiment.

FIG. 5 is a block diagram schematically showing a light emitting device according to an exemplary embodiment of the present disclosure.

FIG. 6 is a circuit diagram showing a pixel according to an exemplary embodiment of the present disclosure.

FIG. 7 is a top plan view showing a light emitting area of a light emitting device according to an exemplary embodiment of the present disclosure.

FIG. 8 is a perspective view showing a portion of a light emitting area shown in FIG. 7.

FIG. 9 is a schematic cross-sectional view taken along a line I1-I1′ of FIG. 7.

FIGS. 10 to 16 are cross-sectional views sequentially showing a manufacturing method of a light emitting device according to an exemplary embodiment of the present disclosure.

FIG. 17 is a perspective view of a light emitting element according to another exemplary embodiment of the present disclosure.

FIG. 18 is a cross-sectional view of a light emitting element according to an exemplary embodiment of FIG. 17.

FIG. 19 is a perspective view of a light emitting device according to another embodiment of the present disclosure.

FIG. 20 is a cross-sectional view of a light emitting element according to an exemplary embodiment of FIG. 19.

FIG. 21 is a perspective view of a light emitting device according to another exemplary embodiment.

FIG. 22 is a schematic cross-sectional view taken along a line II1-II1′ of FIG. 21.

### DETAILED DESCRIPTION

Features of embodiments of the present disclosure, and implementation methods thereof, will be clarified through the following embodiments described with reference to the accompanying drawings. The subject matter of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by the scope of the appended claims, and equivalents thereof.

It will be understood that when an element or a layer is referred to as being ‘on’ another element or layer, it can be directly on another element or layer, or an intervening element or layer may also be present. The same reference numerals designate the same elements throughout the specification.

Although the terms “first,” “second,” and the like are used to describe various constituent elements, these constituent elements are not limited by these terms. These terms are used only to distinguish one constituent element from another constituent element. Therefore, the first constituent elements described herein below may be the second constituent elements within the technical spirit of the present disclosure. When explaining the singular, unless explicitly described to the contrary, it may be interpreted as the plural meaning.

Hereinafter, referring to the accompanying drawings, an exemplary embodiment of the present disclosure will be described in further detail. The same or similar reference numerals are used for the same constituent elements of the drawings.

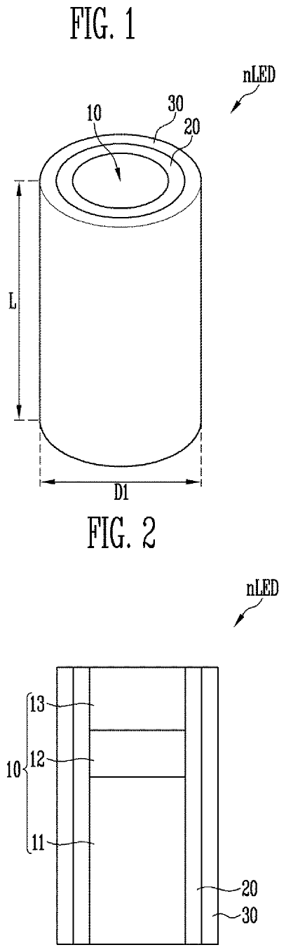

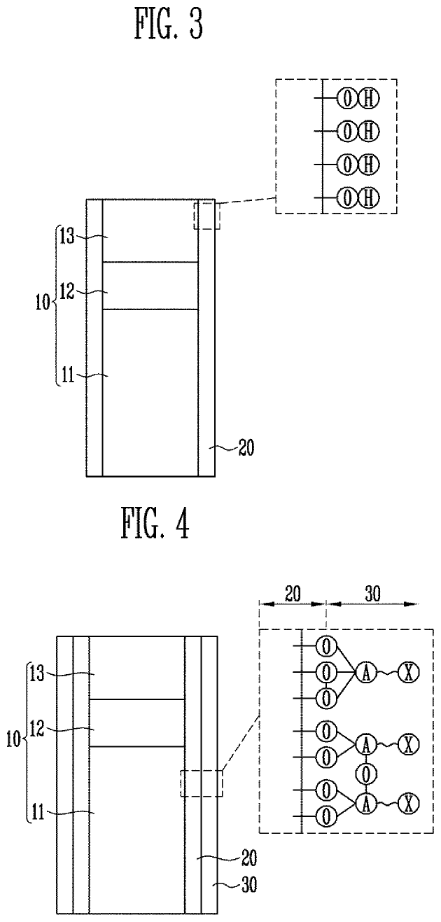

FIG. 1 is a perspective view of a light emitting element according to an exemplary embodiment of the present disclosure. FIG. 2 is a cross-sectional view of a light emitting element according to an exemplary embodiment of the present disclosure. FIGS. 3 and 4 are cross-sectional views showing sequentially a manufacturing method of a light emitting element according to an exemplary embodiment.

Referring to FIGS. 1 and 2, a light emitting element nLED according to an exemplary embodiment of the present disclosure includes a first semiconductor layer 11, a second semiconductor layer 13, and an active layer 12 interposed between the first and second semiconductor layers 11 and 13. For example, the light emitting element nLED may be formed of a laminate in which the first semiconductor layer 11, the active layer 12, and the second semiconductor layer 13 are sequentially stacked in a length direction L. The first semiconductor layer 11, the active layer 12, and the second semiconductor layer 13 may define a light emitting part 10 necessary for the light emitting element nLED to emit light.

In an exemplary embodiment, the light emitting element nLED may be provided in a bar shape extending in one direction. When an extending direction of the light emitting element nLED is referred to as the length direction L, the light emitting element nLED may have one end and the other end in the length direction L.

The length direction L may be interpreted as a direction in which the first semiconductor layer 11, the active layer 12, and the second semiconductor layer 13 are stacked. In addition, the term “bar shape,” as used herein, refers to a rod-like shape or bar-like shape that is long (e.g., with an aspect ratio greater than 1) in the length direction L, such as a circular cylinder or a polygonal cylinder, but a shape of a cross section thereof is not particularly limited. For example, the length L of the light emitting element nLED may be greater than a diameter D1 (or a width of the cross section) thereof. The light emitting element nLED is shown to be a circular cylindrical bar-shaped light emitting element nLED in the drawing, but this is only an example, and a type (or kind) and/or shape of the light emitting element nLED according to the present disclosure is not limited thereto.

In an exemplary embodiment, the light emitting element nLED may have a size that is as small as nano-scale to micro-scale, for example, a diameter D1 and/or a length L of the light emitting element nLED may be hundreds of nanometers to tens of micrometers (e.g., 100 nm to 90 μm). However, the size of the light emitting element nLED in the present disclosure is not limited thereto. For example, a size of the light emitting element nLED may be variously changed according to design conditions of various suitable devices that include a light emitting device including the light emitting element nLED as a light source such as, for example, a display device.

The length L of the light emitting element nLED may have a maximum length of 12 μm. In an exemplary embodiment, the length L of the light emitting element nLED may be in a range of about 1 μm to about 7 μm. In addition, an aspect ratio (ratio of length L to the diameter D1) may be in a range of about 1 to about 7.

In an exemplary embodiment, one of the first and second semiconductor layers 11 and 13 may be at one end of the light emitting element nLED, and the other of the first and second semiconductor layers 11 and 13 may be at the other end of the light emitting element nLED.

For example, the first semiconductor layer 11 may include at least one n-type semiconductor material. For example, the first semiconductor layer 11 may include at least one semiconductor material selected from InAlGaN, GaN, AlGaN, InGaN, AlN, and InN, and may include an n-type semiconductor material doped with a first conductive dopant such as Si, Ge, Sn, and/or the like. However, the material forming the first semiconductor layer 11 is not limited thereto, and the first semiconductor layer 11 may be formed of various suitable materials.

The active layer 12 may be on the first semiconductor layer 11 and may be formed as a single or multiple quantum well structure. In an exemplary embodiment, a cladding layer doped with a conductive dopant may be formed on and/or under the active layer 12. For example, the cladding layer may be formed of an AlGaN layer and/or an InAlGaN layer. According to an exemplary embodiment, materials such as AlGaN and/or AlInGaN may form the active layer 12, but the present disclosure is not limited thereto and various other suitable materials may form the active layer 12.

When an electric field of a set (e.g., predetermined) voltage or more is applied to both ends of the light emitting element nLED, the light emitting element nLED emits light when electron-hole pairs are combined in the active layer 12. By controlling an emission of the light emitting element nLED using this principle, the light emitting element nLED may be used as a light source of various suitable light emitting devices including a pixel of the display device.

The second semiconductor layer 13 may be on the active layer 12 and may include a semiconductor layer of a type (or kind) different from that of the first semiconductor layer 11. For example, the second semiconductor layer 13 may include at least one p-type semiconductor material. For example, the second semiconductor layer 13 may include at least one semiconductor material selected from InAlGaN, GaN, AlGaN, InGaN, AlN, and InN, and may include a p-type semiconductor material doped with a second conductive dopant such as Mg, and/or the like. However, the material forming the second semiconductor layer 13 is not limited thereto, and the second semiconductor layer 13 may be formed of various suitable materials.

In an exemplary embodiment, the light emitting element nLED may include an insulation layer 20 and an organic ligand layer 30 sequentially formed after the first semiconductor layer 11, the active layer 12, and the second semiconductor layer 13 are formed.

For example, the light emitting element nLED may further include an insulation layer 20 formed on an outer peripheral surface, for example, an outer circumferential surface (e.g., an outer surface of a circular cylinder). The insulation layer 20 may be at least formed to surround the outer circumferential surface of the active layer 12 and may further surround at least a portion of the first and second semiconductor layers 11 and 13. However, the insulation layer 20 may expose both ends of the light emitting element nLED having different polarities. For example, the insulation layer 20 may expose without covering one end of each of the first and second semiconductor layers 11 and 13 at both ends of the light emitting element nLED in the length direction L, for example, two bottom surfaces (e.g., upper surface and lower surface) of the circular cylinder. In the present disclosure, however, the light emitting element nLED is not limited to being a circular cylinder and may have various other suitable shapes.

Referring to FIG. 3, in an exemplary embodiment, the insulation layer 20 may have a hydroxyl group (—OH) at one end thereof. For example, the insulation layer 20 may include at least one insulating material selected from SiO₂, Al₂O₃ and TiO₂, but is not limited thereto. However, the constituent material of the insulation layer 20 is not particularly limited thereto, and the insulation layer 20 may be formed of various suitable insulation materials available in the art.

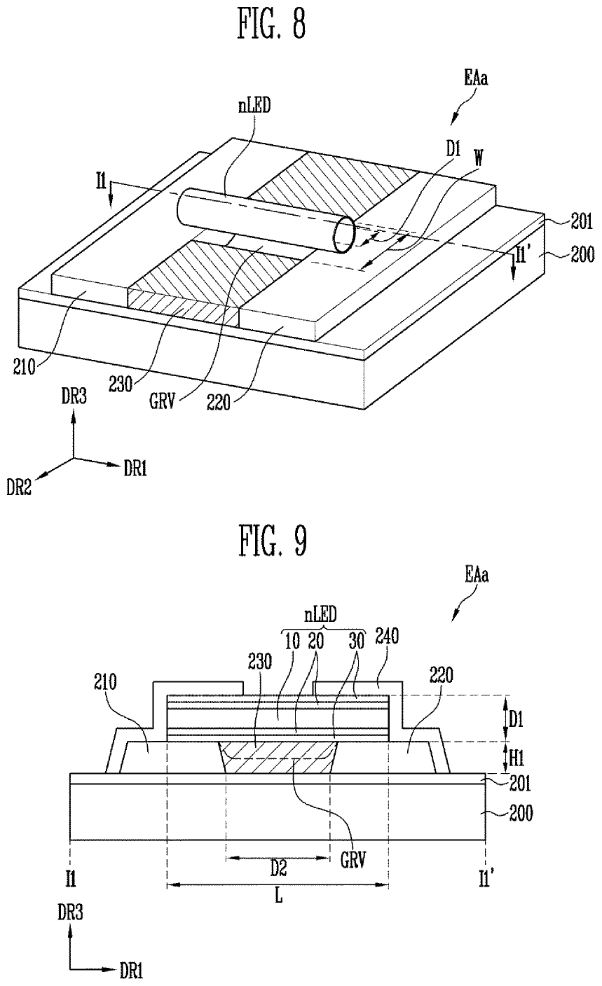

When the insulation layer 20 is formed, it may prevent the active layer 12 from shorting with first and/or second electrode 210 and 220 (or may reduce a likelihood or degree of such a short) described herein below and as shown in FIG. 7 and the like. In addition, by forming the insulation layer 20, it is possible to minimize or reduce surface defects of the light emitting element nLED to improve life-span and efficiency. In addition, when a plurality of light emitting element nLED are closely disposed (e.g., located in close proximity to one another), the insulation layer 20 may prevent an unwanted short that may occur between the light emitting elements nLED (or may reduce a likelihood or degree of such a short).

In some embodiments, the light emitting element nLED may further include an organic ligand layer 30 formed on an outer circumferential surface of the insulation layer 20. Referring to FIG. 4, the organic ligand layer 30 may be formed by performing a surface treatment process on the hydroxyl group (—OH) formed at one end of the insulation layer 20.

The surface treatment process may include a process that removes hydrogen atoms (H) of the hydroxyl group (—OH) formed in the insulation layer 20, and forms a bond between remaining oxygen atoms (O) and the Group 14 elements (e.g., C and Si) coupled with aliphatic or aromatic hydrocarbons

In an exemplary embodiment, the organic ligand layer 30 may have a structure similar to a liquid crystal molecule. For example, the liquid crystal molecule may include at least one compound represented by Chemical Formula 1 or Chemical Formula 2.

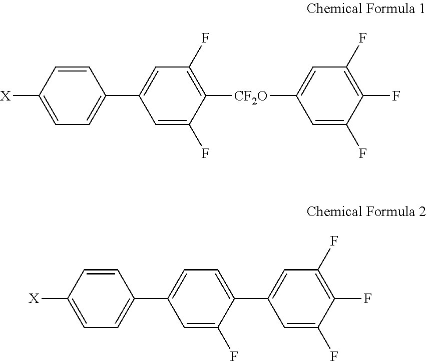

In some embodiments, the organic ligand layer 30 may have a shape (or structure) of an X (e.g., at least one C5 to C24 aliphatic hydrocarbon group or C5 to C20 aromatic hydrocarbon group) bonded to A (e.g., a Group 14 element such as carbon (C) or silicon (Si)). For example, the organic ligand layer 30 may be represented by X-A, where X is at least one C5 to C24 aliphatic hydrocarbon group or C5 to C20 aromatic hydrocarbon group and A is a Group 14 element such as carbon (C) or silicon (Si).

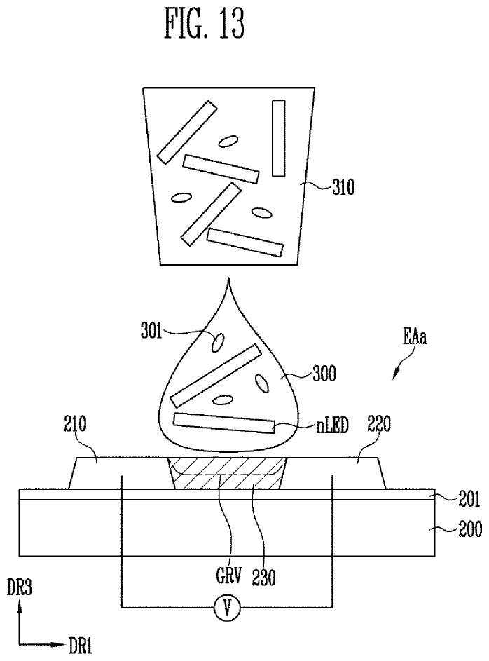

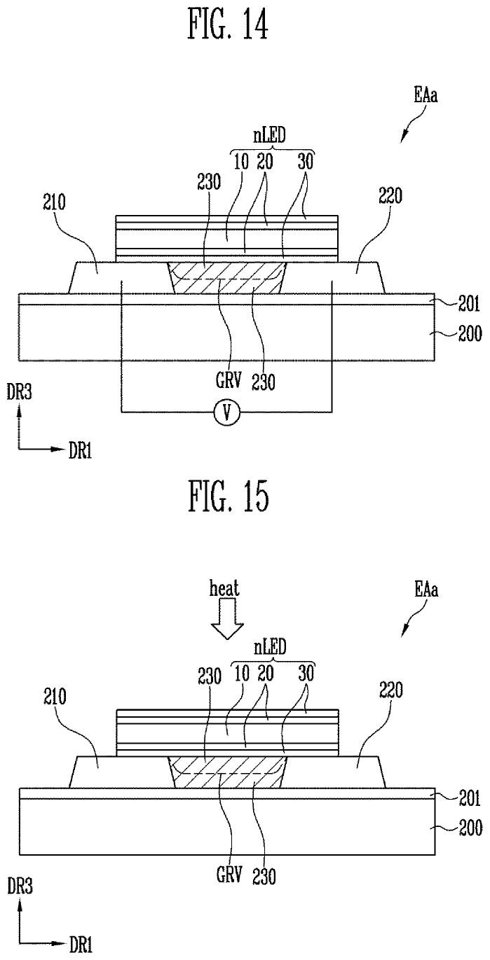

Accordingly, a binding force between the organic ligand layer 30 of the light emitting element nLED and the liquid crystal molecule may be increased. For example, when the liquid crystal molecule moves, the light emitting element nLED including the organic ligand layer 30 may move together with the liquid crystal molecule due to the binding force with the liquid crystal molecule. This will be described herein below with reference to FIGS. 13 and 14.

In some exemplary embodiments, the light emitting element nLED may further include additional constituent elements in addition to the first semiconductor layer 11, the active layer 12 and the second semiconductor layer 13. This will be described herein below with reference to FIGS. 17 and 20.

The light emitting element nLED described herein above may be used as a light source of various suitable light emitting devices. For example, the light emitting element nLED may be used as a light source of a lighting device or a self-luminous display panel.

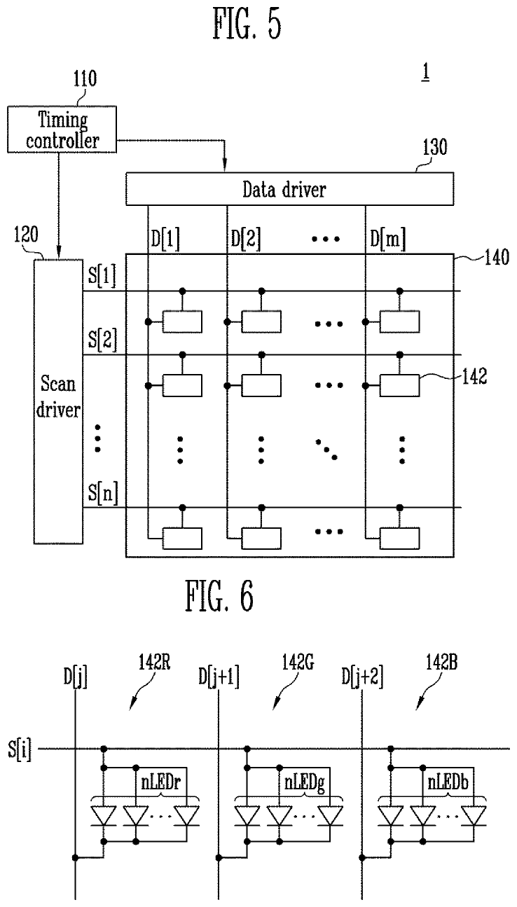

FIG. 5 is a block diagram schematically showing a light emitting device according to an exemplary embodiment of the present disclosure.

A light emitting display device is shown herein as an example of a light emitting device 1 using the light emitting element nLED in FIG. 5, but the light emitting device 1 according to the present disclosure is not limited to the light emitting display device. For example, the light emitting device 1 according to an exemplary embodiment of the present disclosure may be another type (or kind) of light emitting device 1 such as a lighting device, and/or the like.

Referring to FIG. 5, the light emitting device 1 according to an exemplary embodiment of the present disclosure includes a timing controller 110, a scan driver 120, a data driver 130 and a light emitting display panel 140. Herein, the light emitting display panel 140 is shown to be a constituent element separate from the timing controller 110, the scan driver 120 and/or data driver 130 in FIG. 5, but the present disclosure is not limited thereto. For example, at least one of the scan driver 120 and the data driver 130 may be integrally integrated with the light emitting display panel 140 or may be mounted on the light emitting display panel 140.

The timing controller 110 receives various control signals and image data used for driving the light emitting display panel 140 from an external source (e.g., a system for transferring image data). The timing controller 110 rearranges the received image data and transfers the image data to the data driver 130. In addition, the timing controller 110 generates scan control signals and data control signals for driving the scan driver 120 and the data driver 130, and transfers the generated scan control signals and data control signals to the scan driver 120 and the data driver 130, respectively.

The scan driver 120 receives the scan control signal from the timing controller 110 and generates a scan signal in response thereto. The scan signal generated by the scan driver 120 is supplied to pixels 142 through scan lines S[1] to S[n].

The data driver 130 receives a data control signal and image data from the timing controller 110 and generates a data signal in response thereto. The data signal generated by the data driver 130 is output to data lines D[1] to D[m]. The data signal output to the data lines D[1] to D[m] is input to pixels 142 of a horizontal pixel line selected by the scan signal.

The light emitting display panel 140 includes a plurality of pixels 142 coupled to the scan lines S[1] to S[n] and the data lines D[1] to D[m]. In an exemplary embodiment of the present disclosure, each of pixels 142 may include at least one light emitting element nLED as shown in FIG. 1. For example, each of the pixels 142 may include at least one first color light emitting element, second color light emitting element and/or third color light emitting element. These pixels 142 selectively emit light in response to a data signal input from data lines D[1] to D[m] when a scan signal is supplied from the scan lines S[1] to S[n]. For example, during each frame period, each pixel 142 emits light with luminance corresponding to the input data signal. The pixels 142, receiving a data signal corresponding to black luminance, display black by non-light emitting (e.g., by not emitting light) during the corresponding frame period. When the light emitting display panel 140 is an active display panel, the light emitting display panel 140 may be driven by being further receiving first and second pixel power in addition to the scan signal and the data signal.

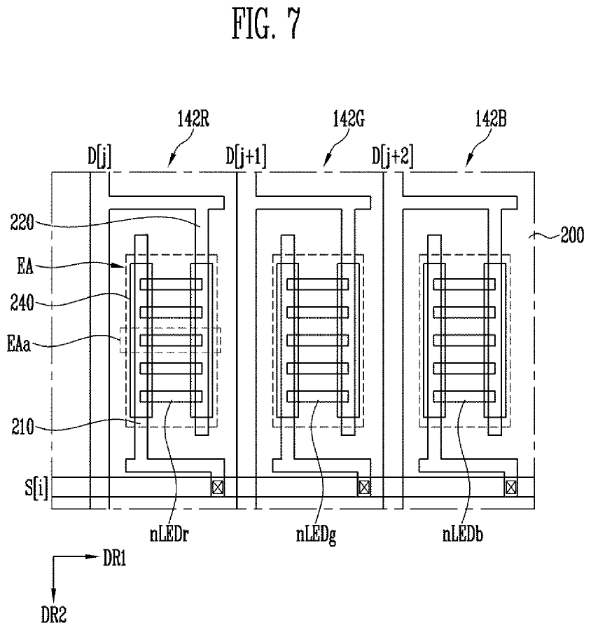

FIG. 6 is a circuit diagram showing a pixel according to an exemplary embodiment of the present disclosure. For better understanding and ease of description, FIG. 6 shows a j-th (j is a natural number) pixel 142R (hereinafter, referred to as a first pixel), a j+1-th pixel 142G (hereinafter, referred to as a second pixel), and a j+2-th pixel 142B (hereinafter, referred to as a third pixel) on an i-th (i is a natural number) horizontal pixel line.

In an exemplary embodiment, the first, second and third pixels 142R, 142G, and 142B may be a red pixel 142R, a green pixel 142G, and a blue pixel 142B that emit light of different colors, for example red, green and blue, respectively, and form one unit pixel. Each of pixels 142R, 142G, and 142B may define a light emitting area that emits each color (e.g., EA of FIG. 7).

However, the present disclosure is not limited thereto. For example, at least one selected from the first to third pixels 142R, 142G, and 142B shown in FIG. 6 may be a pixel that emits light of a color other than red, green, and blue, for example, white. In this case, the light emitting display device may include a color filter layer that overlaps with the light emitting display panel 140 (see FIG. 2) or is integrally formed with the light emitting display panel 140.

In an exemplary embodiment, each of the first to third pixels 142R, 142G, and 142B may include at least two light emitting elements nLEDr, nLEDg, and nLEDb in parallel coupled with each other. In this case, the luminance of each of the first to third pixels 142R, 142G, and 142B may correspond to a sum of the brightness of a plurality of light emitting elements nLEDr, nLEDg, nLEDb included in the corresponding pixel 142R, 142G, and 142B. Thus, because the first to third pixels 142R, 142G, and 142B include a plurality of light emitting elements nLEDr, nLEDg, and nLEDb, for example, a large number of light emitting elements nLEDr, nLEDg, and nLEDb, even if a defect occurs in some of the light emitting elements nLEDr, nLEDg, and nLEDb it is possible to prevent such defects from leading to (or to reduce a likelihood of such defects leading to) defects of the pixels itself (e.g., 142R, 142G, and 142B).

FIG. 7 is a top plan view showing a light emitting area of a light emitting device according to an exemplary embodiment of the present disclosure. For better understanding and ease of description, the light emitting elements are shown to be aligned in a first direction DR1 (e.g., horizontal direction) in FIG. 7, but an arrangement of the light emitting elements is not limited thereto. For example, at least one light emitting element may be aligned in a diagonal direction between first and second electrodes 210 and 220. In addition, a plurality of light emitting elements nLEDr, nLEDg, an nLEDb are shown to be aligned in parallel (e.g., substantially in parallel) with each other, the present disclosure is not limited thereto.

A direction axis is shown in some drawings to describe a relative disposition direction between each constituent element. A first direction DR1, a second direction DR2, and a third direction DR3 may cross each other and correspond to an x-axis direction, a y-axis direction, and a z-axis direction, respectively. The third direction DR3 may correspond to a thickness direction of the light emitting device 1. However, the exemplary embodiment is not limited to a direction shown in the drawing, and it should be understood that the first direction DR1, the second direction DR2, and the third direction DR3 refer to a relative direction that cross each other.

Referring to FIG. 7, the light emitting device 1 includes at least one light emitting area EA, and at least one light emitting element nLEDr, nLEDg and/or nLEDb is provide in each light emitting area EA. In an exemplary embodiment, the light emitting device 1 may be a light emitting display device. In this case, the light emitting device 1 may include a light emitting display panel including a plurality of light emitting areas EA corresponding to each of the pixels 142R, 142G, and 142B.

Each of the pixels 142R, 142G, and 142B includes a light emitting area EA in which at least one light emitting element nLEDr, nLEDg and/or nLEDb is provided. According to an exemplary embodiment, the number of the light emitting elements nLEDr, nLEDg and/or nLEDb provided in each light emitting area EA may be variously changed. For example, as shown in FIG. 5, a plurality of light emitting elements nLEDr, nLEDg and/or nLEDb may be provided in each light emitting area EA.

For example, the first electrode 210 and second electrode 220 may be spaced apart from each other, and at least one light emitting element nLEDr, nLEDg and/or nLEDb may be electrically coupled between the first and second electrodes 210 and 220 in the light emitting area EA. For example, one end of the light emitting elements nLEDr, nLEDg, nLEDb may be on the first electrode 210, and the other end thereof may be on the second electrode 220. According to an exemplary embodiment, a conductive contact layer 240 may be further included on both ends of the light emitting elements nLEDr, nLEDg, and nLEDb to electrically and/or physically and stably couple the light emitting elements nLEDr, nLEDg, and nLEDb to the first and second electrodes 210 and 220, respectively.

The first electrode 210 is coupled to a first electrode line and the second electrode 220 is coupled to a second electrode line to receive a set (e.g., predetermined) power or signal. For example, the first electrode 210 of the passive light emitting display device may be coupled to the corresponding scan line S[i] to receive a scan signal, and the second electrode 220 thereof may be coupled to the corresponding data line D[j], D[j+1], or D[j+2] to receive a data signal.

During at least an aligning process of the light emitting elements nLEDr, nLEDg, and nLEDb among a manufacturing process of the light emitting device 1, the first and second electrodes 210 and 220 may be electrically coupled to first and second shorting bars, respectively. The first shorting bar may be commonly coupled to the first electrode of a plurality of light emitting elements nLEDr, nLEDg, nLEDb, and the second shorting bar may be commonly coupled to the second electrode of a plurality of light emitting elements nLEDr, nLEDg, nLEDb. However, when independently driving a plurality of light emitting elements nLEDr, nLEDg, and nLEDb after manufacturing the light emitting device 1, a coupling between the first and second electrodes 210 and 220 of the plurality of light emitting elements nLEDr, nLEDg, and nLEDb and the first and second shorting bar may be broken. For example, by forming the first and second shorting bar outside a scribing line of the light emitting display panel, the first and second electrode 210 and 220 and the first and second shorting bar may be concurrently (e.g., simultaneously) separated during a scribing process.

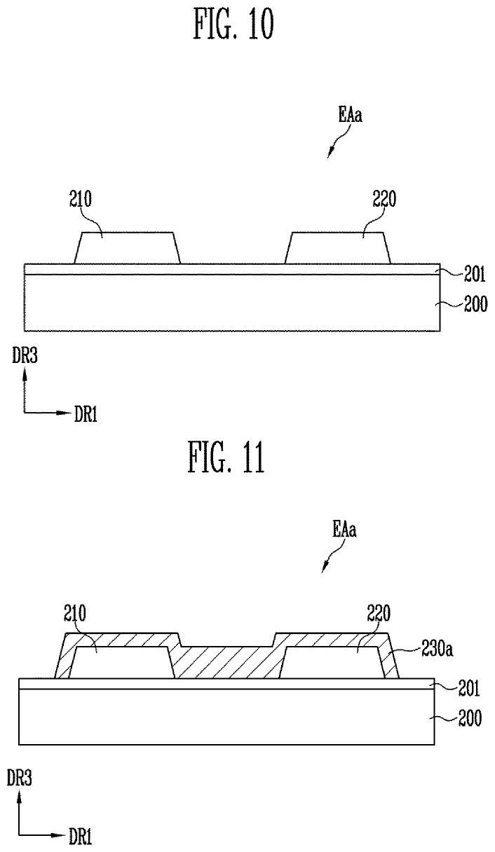

FIG. 8 is a perspective view showing a portion of a light emitting area shown in FIG. 7. FIG. 9 is a schematic cross-sectional view taken along a line I1-I1′ of FIG. 7. In FIG. 8, only the light emitting element is shown and the conductive contact layer is omitted to clearly show a disposition relationship between the light emitting element and the first and second electrodes. In FIG. 9, the conductive contact layer is shown to clearly show a coupling structure between the light emitting element and the first and second electrodes. FIGS. 8 and 9 show some light emitting areas EAa of the entire light emitting area EA of the light emitting device 1. A plurality of first and second electrodes and a plurality of light emitting elements may be provided on a substrate of the light emitting device 1. A description for some light emitting areas EAa of the entire light emitting area EA may be applied to the other light emitting areas.

Referring to FIGS. 8 and 9, the light emitting device 1 according to the exemplary embodiment of the present disclosure includes a substrate 200, the first electrode 210 and the second electrode 220 formed on the substrate 200, and at least one light emitting element nLED coupled between the first and second electrode 210 and 220. In some embodiments, the light emitting device 1 according to the exemplary embodiment of the present disclosure further includes an insulation support 230 that is under the light emitting element nLED, for example, between the substrate 200 and the light emitting element nLED to prevent or reduce separation of the light emitting element nLED.

A plurality of light emitting areas EA may be defined on the substrate 200. For example, the substrate 200 may be an insulation substrate including a transparent material. For example, the substrate 200 may be a flexible substrate including a at least one material selected from polyethersulfone (PES), polyacrylate (polyacrylate), polyetherimide (PEI), polyethylene naphthalate (PEN), polyethylene terephthalate (PET), polyphenylene sulfide (PPS), polyarylate (PAR), polyimide (PI), polycarbonate (PC), cellulose triacetate (TAC), and cellulose acetate propionate (CAP). In some embodiments, the substrate 200 may be a rigid substrate including one of glass and tempered glass. The substrate 200 is not necessarily limited to a transparent substrate. For example, the substrate 200 may be an opaque and/or reflective substrate.

In an exemplary embodiment, the buffer layer 201 may be formed on the substrate 200. However, in another exemplary embodiment, the buffer layer 201 may be omitted.

The first electrode 210 and second electrode 220 are side by side to extend in the second direction DR2 on at least some areas (e.g., light emitting area EA) on the substrate 200. Here, the first electrode 210 and the second electrode 220 are may be spaced apart from each other. In an exemplary embodiment, the first and second electrodes 210 and 220 may be spaced apart by a distance D2 shorter than a length L of the light emitting element nLED. For example, the first and second electrodes 210 and 220 may be spaced apart by the distance D2 such that both ends of the light emitting element nLED may be coupled between the first and second electrodes 210 and 220 while both ends of the light emitting element nLED are stably on the first and second electrodes 210 and 220, respectively. The first and second electrodes 210 and 220 may be formed of at least one of various suitable conductive electrode materials.

In an exemplary embodiment, the first electrode 210 and the second electrode 220 may be on the same (e.g., substantially the same) plane on the substrate 200 and have the same (e.g., substantially the same) height H1. When the first and second electrodes 210 and 220 have the same (e.g., substantially the same) height H1, the light emitting element nLED may be more stably on the first and second electrodes 210 and 220.

One end of the light emitting element nLED is on the first electrode 210 and the other end thereof is on the second electrode 220. When the insulation layer 20 is between the light emitting element nLED and the first and second electrodes 210 and 220, an electrical coupling between the light emitting element nLED and the first and second electrodes 210 and 220 may be blocked. Therefore, according to an exemplary embodiment, the light emitting element nLED may be stably coupled to the first and second electrodes 210 and 220 by removing at least a portion of the insulation layer 20 or by additionally forming the conductive contact layer 240.

The conductive contact layer 240 electrically couples both ends of the light emitting element nLED to the first and second electrodes 210 and 220, respectively. For example, the conductive contact layer 240 may be formed to cover one end of the light emitting element nLED and an upper portion of the exposed end of the first electrode 210, and to cover the other end of the light emitting element nLED and an upper portion of the exposed end of the second electrode 220, respectively. For example, both sides of the light emitting element nLED not covered by the insulation layer 20 may be electrically coupled to the first and second electrodes 210 and 220 through the conductive contact layer 240.

The conductive contact layer 240 may not only electrically couple the light emitting element nLED to the first and second electrodes 210 and 220, but also provide a bonding function for physically coupling the light emitting element nLED and the first and second electrodes 210 and 220.

In an exemplary embodiment, the conductive contact layer 240 may be formed of a transparent conductive material such as ITO, IZO, ITZO, and/or the like so that light emitted from the light emitting element nLED may be transmitted through the conductive contact layer 240. However, the present disclosure is not limited thereto, and a material constituting the conductive contact layer 240 may be changed (e.g., to be opaque and/or reflective).

The insulation support 230 is formed under the light emitting element nLED, for example, between the substrate 200 and the light emitting element nLED. For example, the insulation support 230 may be formed to fill a vertical space between the substrate 200 and the light emitting element nLED. The insulation support 230 stably supports the light emitting element nLED, thereby preventing or reducing separation of the light emitting element nLED aligned between the first and second electrodes 210 and 220. For example, by forming the insulation support 230, it is possible to prevent or reduce separation of the light emitting element nLED from the aligned disposition.

In some embodiments, the insulation support 230 may be aligned in an extending direction (e.g., second direction DR2) of the first and second electrodes 210 and 220, and may include at least one groove GRV extending in a direction (e.g., first direction DR1) that crosses the extending direction. At least one light emitting element nLED may be on the at least one groove GRV. An exemplary embodiment of the present disclosure shows a case where one light emitting element nLED is in one groove GRV.

In an exemplary embodiment, the insulation support 230 may include at least one organic insulation layer. In addition, the insulation support 230 may optionally further include at least one inorganic insulation layer. For example, the insulation support 230 may be formed of an organic insulation layer in an upper region where at least one groove GRV is formed.

The groove GRV may have a ‘U’ shape. However, exemplary embodiments are not limited thereto. The groove GRV may be provided in a ‘V’ shape or in various other suitable shapes.

In an exemplary embodiment, the light emitting elements nLED in the at least one groove GRV may have an arrangement shape corresponding to the shape of the groove GRV. For example, each of the light emitting element nLED may be a bar-shaped light emitting diode, and the bar-shaped light emitting diodes may be arranged to have a length L extending in the first direction DR1 in which the GRV extends.

In addition, each groove GRV may be formed to stably receive at least one light emitting element nLED thereon. For example, each groove GRV may have a width W greater than a diameter D1 or a width of each of the light emitting elements nLED in the second direction DR2. In some embodiments, according to the exemplary embodiment, each groove GRV may have a depth corresponding to at least half of a thickness (diameter D1 when the light emitting elements nLED have a cylindrical shape) of each of the light emitting elements nLED in the third direction DR3, but the depth of the groove GRV is not limited thereto.

In manufacturing the light emitting device according to the exemplary embodiment described herein above, the light emitting elements nLED are provided on the insulation support 230 after forming the groove GRV extending in the first direction DR1 in the insulation support 230 on the substrate 200. In this case, the light emitting element nLED are aligned between the first and second electrodes 210 and 220 to have a more uniform direction by the groove GRV of a surface of the insulation support 230. For example, as compared with a case where the groove GRV is not formed, a greater number of light emitting elements nLED among the light emitting element nLED supplied to the light emitting area EA may be in a horizontal direction in the first direction DR1 between the first and second electrodes 210 and 220.

However, the groove GRV may be omitted in the insulation support 230 of some exemplary embodiments.

FIGS. 10 to 16 are cross-sectional views sequentially showing a manufacturing method of a light emitting device according to an exemplary embodiment of the present disclosure. In the present specification, although each step is described as being performed sequentially according to the order of drawing, it should be apparent to those of ordinary skill in the art that the order of each step may be changed, some steps may be omitted, or other steps may be added between each step unless stated otherwise.

Referring to FIG. 10, the first electrode 210 and the second electrode 220 are formed to be spaced apart from each other in the light emitting area EA on the substrate 200. According to an exemplary embodiment, the buffer layer 201 may be formed before forming the first electrode 210 and the second electrode 220. According to an exemplary embodiment, the forming of the first electrode 210 and the second electrode 220 may be a step of forming the first electrode 210 and the second electrode 220 by forming a conductive layer on the substrate 200 and then patterning the conductive layer.

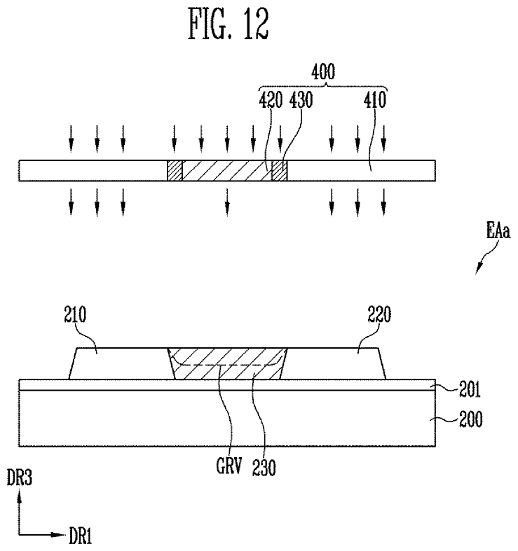

Referring to FIG. 11, the insulating layer 230a is formed on the light emitting area EA where the first and second electrodes 210 and 220 and the light emitting element nLED is to be formed. The insulation layer 230a may be at least one organic insulation layer and/or an inorganic insulation layer. For example, the organic insulation layer 230a may be applied on the light emitting area EA.

The organic insulation layer 230a may be applied by a slit coating, a spin coating, a gravure printing, and/or the like. The organic insulation layer 230a may include a photosensitive material. The photosensitive material may be a positive-type photosensitive material or a negative-type photosensitive material. The present exemplary embodiment shows a case where the organic insulation layer 230a includes a positive-type photosensitive material, but is not limited thereto.

Referring to FIG. 12, the organic insulation layer 230a is patterned through a photo process using a mask 400. For example, after curing by UV exposure a front surface (e.g., a surface on which the light emitting element nLED is formed) of the substrate 200 on which the organic insulation layer 230a including the positive-type photosensitive material is formed, the insulation layer 230a may be patterned so that the insulating layer 230a on the first and second electrodes 210 and 220 may be removed.

In an exemplary embodiment, the mask 400 may be a half-tone mask. The half-tone mask 400 includes a transmissive portion 410, a semi-transmissive portion 420, and a non-transmissive portion 430. The semi-transmissive portion 420 corresponds to an area where the groove GRV is to be formed, the non-transmissive portion 430 corresponds to an area overlapping with the first and second electrodes 210 and 220, and the transmissive portion 410 corresponds to the other area. Next, when the organic insulation layer 230a undergoing an exposure process goes through a development process, the insulation support 230 including the groove GRV may be completed as shown in FIG. 8.

Referring to FIG. 13, at least one light emitting element nLED is injected into the light emitting area EA in which the first electrode 210, the second electrode 220 and the insulation support 230 are formed. As another example of a method of injecting the light emitting element nLED onto the first and second electrodes 210 and 220, an inkjet printing method or a micro drop method of 50 pL or less corresponding thereto may be used. For example, a discharge port 310 may be in the light emitting area EA, and a solution 300 including the light emitting element nLED may be dropped, and the light emitting element nLED may be injected into the light emitting area EA.

In an exemplary embodiment, the solution 300 may include a plurality of liquid crystal molecules 301 as a solvent. The liquid crystal molecule 301 may include at least one compound represented by Chemical Formula 1 or Chemical Formula 2 described herein above.

However, the method of injecting the light emitting element nLED into the light emitting area EA is not limited thereto, and the method of injecting the light emitting element nLED may be changed. For convenience of illustration, a size or ratio of some constituent elements may be shown differently from an actual size or ratio thereof in FIG. 13. For example, a length of the light emitting element nLED included in the solution 300 may be longer than a distance between the first and second electrodes 210 and 220.

In an exemplary embodiment, the solution 300 including the light emitting element nLED may be dropped into the light emitting area EA while a direct current voltage or alternating current voltage is applied to the first and second electrodes 210 and 220.

Referring to FIG. 14, the light emitting element nLED is aligned to be physically and/or electrically coupled between the first and second electrodes 210 and 220. For example, the light emitting element nLED may be self-aligned on at least one area of the first and second electrodes 210 and 220.

In an exemplary embodiment, a self-alignment of the light emitting element nLED may be induced by applying a direct current voltage or alternating current voltage to the first and second electrodes 210 and 220. For example, when voltage is applied to the first and second electrodes 210 and 220, bipolarity is induced in the light emitting element nLED by an electric field formed between the first and second electrodes 210 and 220. Accordingly, the light emitting element nLED is self-aligned between the first and second electrodes 210 and 220.

When the electric field is formed by applying the direct current voltage or alternating current voltage to the first and second electrodes 210 and 220, a plurality of liquid crystal molecules 301 may be generally aligned in the first direction DR1. When the electric field is formed, the light emitting element nLED having a binding force with the liquid crystal molecule 301 may be subjected to an external force so that the light emitting element nLED are automatically aligned by the alignment of the liquid crystal molecule 301.

Accordingly, the light emitting element nLED may increase a degree of alignment due to physical effects by the alignment of the liquid crystal molecule, thereby increasing a contact rate between the first and second electrodes 210 and 220. For example, a probability of a physical and/or electrical coupling between the light emitting elements and the first and second electrodes 210 and 220 may increase. By increasing the degree of alignment of the light emitting element nLED, the luminance in the pixel unit may be increased.

Referring to FIG. 15, the light emitting elements are aligned on the first and second electrodes 210 and 220, and then the light emitting elements are heat-treated. In an exemplary embodiment, a heat-treatment may be performed at high temperature of 80° C. or more. Through the heat-treatment, the binding force between the first and second electrodes 210 and 220 and the light emitting element nLED may be increased.

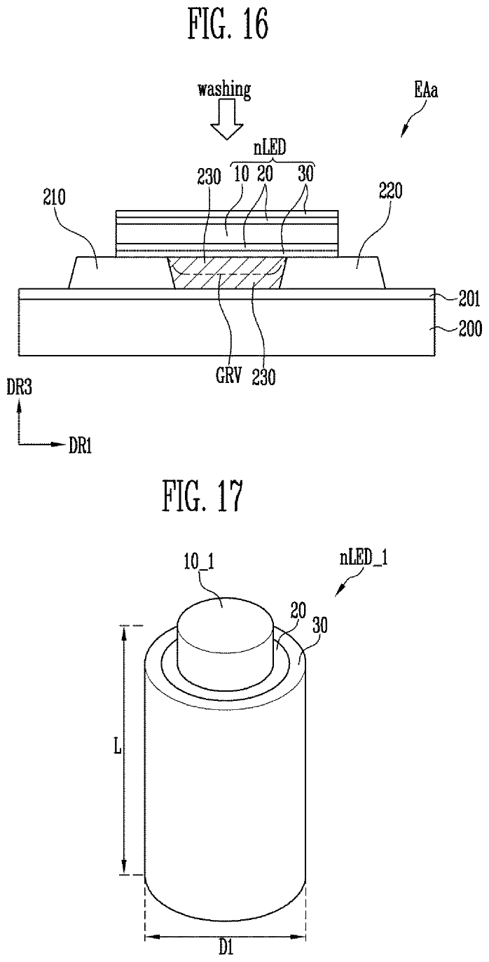

Referring to FIG. 16, after the heat-treatment, the liquid crystal molecule 301 is removed. In an exemplary embodiment, the liquid crystal molecule 301 may be removed through a separate washing process. The washing process may remove the liquid crystal molecule 301 using a single solvent or a mixed solvent, including at least one selected from, for example, tetrahydrofuran (THF), isopropyl alcohol (IPA), deionized (Di-water), N-Methyl-2-pyrrolidone (NMP), and acetonitrile.

However, in another exemplary embodiment, the liquid crystal molecule 301 may be removed by using a vacuum dry method in addition to the method using the solvent described herein above.

After the process of aligning the light emitting element nLED on the first and second electrodes 210 and 220 (after removing the liquid crystal molecule 301), a process of forming the conductive contact layer 240 for physically and/or electrically coupling the light emitting device nLED to the first and second electrodes 210 and 220 may be performed. At this time, the washing process may be performed prior to forming the conductive contact layer 240 in order to prevent or reduce peeling of a contact material. This washing process may form ohmic contacts between the light emitting element nLED and the first and second electrodes 210 and 220.

However, when the insulation support 230 does not exist, an empty space exists between the substrate 200 and the light emitting element nLED. When the washing process is performed in this state, a detachment of the light emitting element nLED is likely to occur. Therefore, even if a plurality of light emitting elements nLED are aligned on the substrate 200, a large number of light emitting elements nLED may be separated from an aligned position. In addition, when the insulation support 230 does not exist, a separation of the light emitting elements nLED may occur during other subsequent processes in addition to the washing process. Therefore, in embodiments of the present disclosure, before the washing process, the insulation support 230 capable of preventing or reducing separation of the light emitting element nLED is formed in advance.

Next, a light emitting element and a light emitting device according to another exemplary embodiment will be described. Hereinafter, the description for the same constituent elements as those in FIGS. 1 to 16 will not be repeated and the same or similar reference numerals will be used for the same constituent elements as those in FIGS. 1 to 16.

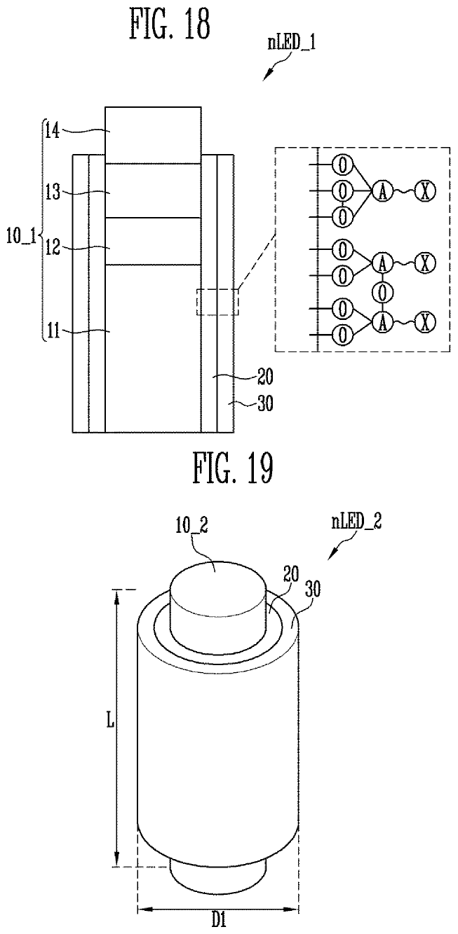

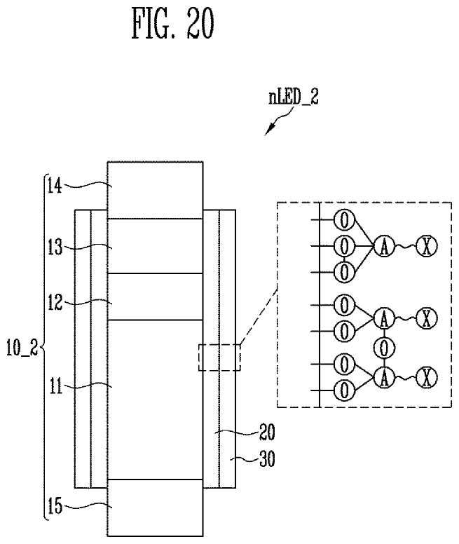

FIG. 17 is a perspective view of a light emitting element according to another exemplary embodiment of the present disclosure. FIG. 18 is a cross-sectional view of a light emitting element according to an exemplary embodiment of FIG. 17. FIG. 19 is a perspective view of a light emitting device according to another embodiment of the present disclosure. FIG. 20 is a cross-sectional view of a light emitting element according to an exemplary embodiment of FIG. 19.

Referring to FIGS. 17 to 20, the light emitting element nLED_1 may further include at least one electrode layer 14 at one end of the second semiconductor layer 13 as shown in FIGS. 17 and 18 in comparison with the light emitting element nLED according to an exemplary embodiment of FIGS. 1 and 2. In addition, the light emitting element nLED_2 may further include at least one other electrode layer 15 at one end of the first semiconductor layer 11 as shown in FIGS. 19 and 20.

Each of the electrode layers 14 and 15 may be an ohmic contact electrode, but the present disclosure is not limited thereto. In addition, each of the electrode layers 14 and 15 may include metal and/or metal oxide. For example, each of the electrode layers 14 and 15 may include Cr, Ti, Al, Au, Ni, ITO, IZO, ITZO, an oxide thereof or alloy thereof alone or in combination. In addition, according to an exemplary embodiment, the electrode layers 14 and 15 may be substantially transparent or translucent. Accordingly, light generated from the light emitting element nLED_2 may transmit (e.g., may be transmitted through) the electrode layers 14 and 15 to be emitted to the outside of the light emitting element nLED_2. The electrode layers 14 and/or 15 together with the first semiconductor layer 11, the active layer 12, and the second semiconductor layer 13 may define a light emitting part 10_1, 10_2.

According to an exemplary embodiment, the insulation layer 20 may or may not at least partially surround the outer peripheral surface (e.g., circumferential surface) of the electrode layers 14 and 15. In other words, the insulation layer 20 may be selectively formed on the surface of the electrode layers 14 and 15. In addition, the insulation layer 20 is formed to expose both ends of the light emitting element nLED_2 having different polarities, and for example, may expose at least one area of the electrode layers 14 and 15. In some embodiments, the insulation layer 20 may not be provided.

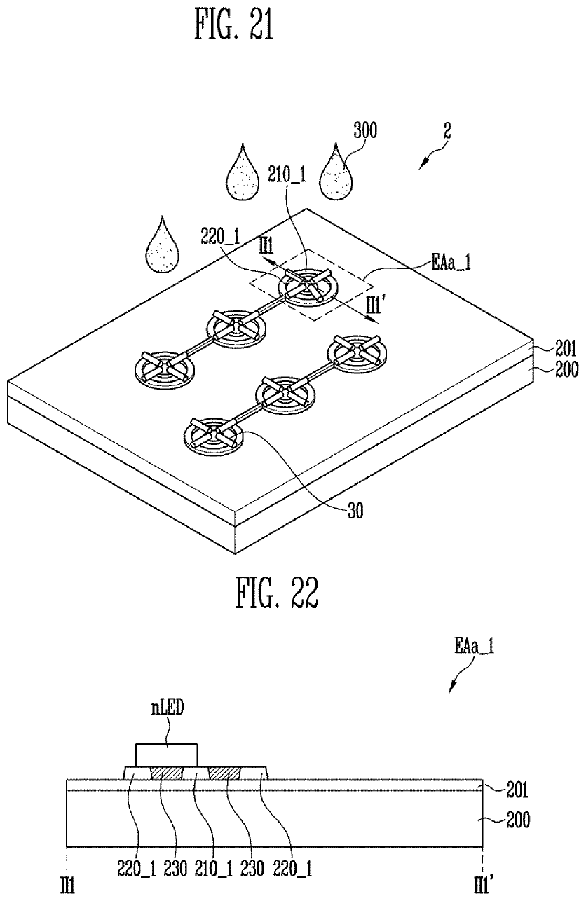

FIG. 21 is a perspective view of a light emitting device according to another exemplary embodiment. FIG. 22 is a schematic cross-sectional view taken along a line II1-II1′ of FIG. 21.

Referring to FIGS. 21 and 22, a light emitting device 2 according to an exemplary embodiment of the present disclosure is different from the light emitting device 1 according to an exemplary embodiment of FIGS. 8 and 9 in that the first electrode 210_1 and the second electrode 220_1 of the light emitting area EAa_1 have different shapes in a plane view.

A plurality of first electrodes 210_1 may be formed, and the plurality of first electrodes 210_1 may be spaced apart from each other with a set (e.g., predetermined) interval therebetween.

The second electrode 220_1 may have a circular shape extending in a circumferential direction with respect to the first electrode 210_1. At this time, the first electrode 210_1 and the second electrode 220_1 may be spaced apart from each other at a set (e.g., predetermined) interval.

Due to a potential difference between the first and second electrodes 210_1 and 220_1, an electric field in a radiation direction, for example, the radiation direction around the first electrode 210_1 may be formed, and the light emitting element nLED having a binding force with the liquid crystal molecule by induction of the electric field, may be arranged.

While exemplary embodiments of the disclosure are described with reference to the attached drawings, those with ordinary skill in the technical field to which the present disclosure pertains will understand that the present disclosure can be carried out in other specific forms without changing the technical idea or essential features. Accordingly, the above-described exemplary embodiments should be considered in descriptive sense only and not for purposes of limitation.

What is claimed is:

1. A manufacturing method of a light emitting device, the method comprising:
forming a first electrode and a second electrode spaced apart from each other on a substrate on which a light emitting area is defined;
injecting a solution including a light emitting element and a liquid crystal molecule into the light emitting area; and
aligning the light emitting element such that the first electrode and the second electrode are electrically coupled;
wherein the light emitting element comprises:
a first semiconductor layer;
a second semiconductor layer;
an active layer interposed between the first semiconductor layer and the second semiconductor layer;
an insulation layer formed to surround an outer surface of the active layer; and
an organic ligand layer formed on an outer surface of the insulating layer.

2. The manufacturing method of claim 1, further comprising:
heat-treating at a high temperature of 80° C. or more after the aligning.

3. The manufacturing method of claim 2, further comprising:
removing a liquid crystal after the heat-treating.

4. The manufacturing method of claim 3, wherein:
in the removing of the liquid crystal, the liquid crystal is removed using a solvent comprising at least one selected from tetrahydrofuran (THF), isopropyl alcohol (IPA), deionized water (Di-water), N-Methyl-2-pyrrolidone (NMP), and acetonitrile.

5. The manufacturing method of claim 1, wherein:
in the aligning, a direct current voltage or alternating current voltage is applied to the first electrode and the second electrode.

6. The manufacturing method of claim 1, wherein:
the first and second electrodes are side by side to extend in a first direction in at least one area on the substrate.

7. The manufacturing method of claim 6, further comprising:
applying an organic insulation layer on the first electrode, the second electrode, and the light emitting area before injecting the solution.

8. The manufacturing method of claim 7, further comprising:
forming a groove extending in a second direction crossing the first direction in the organic insulation layer through a photo process after the applying the organic insulation layer.

9. The manufacturing method of claim 8, wherein:
in the forming of the groove, the photo process is performed using a halftone mask.

10. The manufacturing method of claim 9, wherein:
a stacked direction of the first semiconductor layer, the active layer and the second semiconductor layer in the light emitting element is the second direction after the aligning.

11. The manufacturing method of claim 10, wherein,
the groove has a width greater than a diameter or a width of the light emitting element.

12. The manufacturing method of claim 1, wherein:
the injecting the solution is performed by an inkjet process or a fine drop process of 50 pL or less.

13. A light emitting element comprising:
a first semiconductor layer;
a second semiconductor layer;
an active layer interposed between the first semiconductor layer and the second semiconductor layer;
an insulation layer formed to surround an outer surface of the active layer; and
an organic ligand layer formed on at least a portion of the insulation layer.

14. The light emitting element of claim 13, wherein:
the organic ligand layer includes at least one C5 to C24 aliphatic hydrocarbon group or C5 to C20 aromatic hydrocarbon group bonded to a Group 14 element.

15. The light emitting element of claim 13, wherein:
the light emitting element further includes a first electrode layer on one side of the first semiconductor layer and a second electrode layer on one side of the second semiconductor layer.

16. The light emitting element of claim 13, wherein:
the insulation layer has a hydroxyl group at one end.

17. The light emitting element of claim 13, wherein:
the light emitting element has a length of 1 μm to 7 μm and an aspect ratio of 1 to 7.

18. A light emitting device comprising:
a substrate on which a plurality of light emitting areas are defined;
first and second electrodes on the substrate and side by side in at least a portion of the light emitting area; and
a light emitting element having one end on the first electrode and an other end on the second electrode,
wherein the light emitting element includes an organic ligand layer formed on at least a portion of a surface thereof.

19. The light emitting device of claim 18, further comprising:
an insulating support between the substrate and the light emitting element and including a groove,
wherein the light emitting element is in the groove.

20. The light emitting device of claim 18, further comprising:
a conductive contact layer electrically coupling the one end of the light emitting element and the first electrode, and electrically coupling the other end of the light emitting element and the second electrode.
